(19) United States
(12) Patent Application Publication
(10) Pub. No.: US 2006/0170491 A1
(43) Pub. Date: Aug. 3, 2006

(54) Optoelectronic sensor

(76) Inventors: Martin Wany, Schindellegi (CH); Peter Mario Schwider, Siebnen (CH)

Correspondence Address: TAROLLI, SUNDHEIM, COVELL & TUMMINO L.L.P., 1300 EAST NINTH STREET, SUITE 1700, CLEVEVLAND, OH, 44114, US

(21) Appl. No.: 10/533,682

(22) PCT Filed: Oct. 28, 2003
(86) PCT No.: PCT/CH03/00704

§ 371 Date: Dec. 7, 2005

(30) Foreign Application Priority Data
Oct. 29, 2002 (CH) 181002

(51) Int. Cl. H03F 7/00

(52) U.S. Cl. 330/4.9

(57) ABSTRACT

Disclosed is an optoelectronic sensor comprising at least one photodiode (1) which can be connected to a first potential (Vᵣₑₛₑₜ,Vᵣₑₛₑₜ₁) via a first transistor (T1) or a first diode (D1). Said photodiode (1) can also be connected to the input of a readout amplifier (T3) via a second transistor (T2). A third transistor (T5), via which the input of the readout amplifier (T3) can be connected to a second potential (Vᵣₑₛₑₜ, Vᵣₑₛₑₜ₂), is disposed between the second transistor (T2) and the input of the readout amplifier (T3). The inventive optoelectronic sensor further comprises means (C2) for temporarily storing the integrated signal value until readout time, whereby an optoelectronic sensor having a great dynamic range is created, i.e. the sensitivity thereof towards small signals is increased while the sensitivity thereof towards large signals is reduced, said optoelectronic sensor additionally allowing the signal value to be stored in the pixel until readout time following integration (global shutter exposure control).

### TECHNICAL FIELD

The present invention relates to an optoelectronic sensor comprising at least one photodiode which can be connected to a first potential via a first transistor.

### PRIOR ART

To an increasing extent, image sensors are being implemented in CMOS technology. In contrast to CCD technology, this technology makes it possible to produce nonlinear characteristic curves of the output signal in response to the input signal.

For an equal greyscale resolution, a nonlinear characteristic curve makes it possible to process a higher contrast within an image, without saturation of the image occurring, compared to what is possible with a linear characteristic curve.

In the past, nonlinear characteristic curves have been produced in a variety of ways. For example, U.S. Pat. No. 4,473,836 describes the production of a nonlinear characteristic curve by means of logarithmic compression. WO 01/46655 describes the production of a nonlinear characteristic curve by means of combined linear-logarithmic compression. Other sources use so-called clamping for this purpose (T. F. Knight, PhD. thesis, MIT, June 1983). In principle, this always involves a reduction in the sensitivity of the optoelectronic sensor at high light energies. On the other hand, the method of skimming (cf. for example IEEE Transactions on circuits and systems for video technology, Vol. 7, No 4, August 1997) makes it possible to increase the sensitivity at low optical intensities.

In order to record rapidly moving images, or scenes, which are illuminated by means of pulsed light sources (flash lighting), sensors which have a so-called “global shutter” exposure control are used. This means sensors which, by means of a “sample and hold” component in the pixel, make it possible to store the integrated signal value until the readout time.

### SUMMARY OF THE INVENTION

It is therefore an object of the invention to provide an optoelectronic sensor which has an increased dynamic range and “global shutter” exposure control. This essentially involves both restricting the sensitivity of the sensor at high light energies and, and the same time, making it possible to increase in the sensitivity at low optical intensities. The present invention relates to an optoelectronic sensor comprising at least one photodiode which can be connected to a first potential via a first transistor or a first diode.

This object is achieved in that the photodiode can furthermore be connected to the input of a readout amplifier via a second transistor, a third transistor via which the input of the readout amplifier can be connected to a second potential furthermore being arranged between the second transistor and the input of the readout amplifier. There are furthermore means (C2) which allow temporary storage of the integrated signal value until the readout time.

The crux of the invention is therefore to combine the possibilities of increasing the sensitivity at low optical intensities with the possibilities of reducing the sensitivity of the sensor at high light energies, and at the same time retaining the “global shutter” exposure control.

The invention proposes a circuit which is suitable for integration into a one- or two-dimensional array of optoelectronic sensor elements (image sensors), and which makes it possible to produce nonlinear characteristic curves both by increasing the sensitivity for optical signals of low intensity and by reducing the sensitivity for optical signals of high intensity. The proposed circuit can likewise be used in two-dimensional arrays and be read out with the signal timing for double sampling.

According to a first preferred embodiment of the present invention, in the case of a first transistor, the first and second potentials are at an essentially identical voltage level. In the case of a first diode, this circuit is not possible since the first potential must in this case be regulated independently of the second potential in order to control the effective diode threshold voltage. The “sample and hold” component is preferably produced by the second transistor and the stray capacitances which are connected to the input of the readout buffer. These stray capacitances likewise form the conversion capacitor in the amplification mode for small signals. In order to better control this conversion capacitor, an additional capacitor to the ground potential may be connected to this node. This capacitance is usually in the range of a few femtofarads. In order to permit amplification of small signals, the total capacitance connected to the input of the readout buffer has to be less than the stray capacitance of the photodiode.

According to another preferred embodiment of the invention, the output of the readout amplifier or readout buffer is connected to a column bus via a row selection transistor. Typically, all of the transistors used in the circuit are designed as MOS transistors. The following description is based on an implementation with N-type MOS transistors (NMOS), but the invention also covers the possible implementation with P-type MOS transistors or a combination of both transistor types. When PMOS transistors are implemented, all the voltages are to be inverted with respect to the NMOS transistor at the place specified, as is well known and obvious to the reader skilled in the art.

Another preferred embodiment of the present invention is distinguished in that the gate voltage of the second transistor is controlled so that the current generated by the photodiode discharges only a capacitor at the input of the readout amplifier in a first phase of the integration time, and in that the gate voltage of the first transistor, or respectively the first potential in the case of a first diode, is controlled so that some or all of the current generated by the photodiode is compensated for by the channel of the first transistor or respectively by the first diode in a last phase of the integration time. This operation ensures that the sensitivity is reduced for high intensities and that the sensitivity is increased for low intensities. Depending on the intensity, such a sensor will remain in the first phase (low signals) throughout integration time or continue through to the last phase (large signals). Typically, the voltages are in this case adjusted so that the gate voltage of the first transistor is lower than the gate voltage of the second transistor and so that the gate voltage of the first transistor is higher than the saturation signal of the readout buffer at least by a threshold voltage. In the case of using a diode instead of the first transistor, the anode voltage (first potential) of the diode is adjusted so that the anode voltage minus the diode threshold voltage is lower than the gate voltage minus the threshold voltage of the second transistor and so that the anode voltage minus the diode threshold voltage is greater than the saturation signal of the readout buffer. It then proves expedient to adjust to the gate voltages (or respectively the gate voltage and the anode voltage in the case of a diode), so that the difference between the two voltages is greater than the tolerance of the threshold voltages plus the tolerance of the voltage values, this difference particularly preferably being selected to be >100 mV. This is for typical light intensities in the range of nW/cm²-mW/cm².

After the integration time, the second transistor is opened so that the conversion node (storage node) is isolated from the photodiode. In this phase, until the end of the readout phase, the gate of the first transistor is kept at a potential which is greater than the ground voltage at least by a threshold voltage. In the case of a first diode, the latter will similarly be adjusted to the first potential plus the effective diode threshold voltage. This ensures that charge carriers accumulated by the photodiode do not fully discharge the photodiode and overflow to the storage node, but are compensated for by the channel of the first transistor or respectively the first diode if the potential of the photodiode reaches a value close to the ground voltage (large optical intensities).

In another preferred embodiment of the invention, the gate voltages of the first and second transistors can be varied during the integration time. The characteristic response curve (sensitivity as a function of intensity) of the sensor or sensor array can thus be adjusted even more variably if need be, or respectively depending on the intensity distribution of the incident light over an array of sensor cells. During the “hold” phase, care should then be taken that the gate voltage of the first transistor remains at least at a value which prevents full discharge of the photodiode but is lower than the smallest value used for the gate voltage of the second transistor during the integration phase. Similarly, the first diode must be controlled accordingly via the first potential.

Other preferred embodiments of the optoelectronic sensor according to the invention are described in the dependent claims.

The present invention furthermore relates to a method for operating an optoelectronic sensor as described above. In particular, the method is distinguished in that the gate voltage of the first transistor, or respectively the first potential in the case of a first diode, is respectively adjusted or controlled so that charge carriers accumulated by the photodiode discharge only a conversion node capacitor in a first phase of the integration time, in that charge carriers accumulated by the photodiode discharge both a photodiode capacitor and said conversion node capacitor in a second phase after an equal potential has been reached at the output of the photodiode and at the input of the readout amplifier, and in that after the output of the photodiode has fallen below the threshold value of the first transistor or respectively the diode threshold value of the first diode, charge carriers accumulated by the photodiode are at least partially made available via the first transistor or respectively via the first diode in a third phase, and in that after the integration time has elapsed the second transistor is opened and the gate voltage of the first transistor, or respectively the first potential in the case of a first diode, is adjusted so as to prevent full discharge of the photodiode. This mode of operation achieves the aforementioned reduction in the sensitivity for high intensities and respectively the increase in the sensitivity for low intensities, and the possibility of storing the signal value in the pixel until the readout time after the integration time has elapsed (“global shutter” exposure control). Preferably, a procedure may then be adopted such that the gate voltage of the second transistor is adjusted during the reset phase and during the integration phase so that the gate voltage minus the threshold voltage is lower than the reset voltage which is set at the input of the readout amplifier, and so that the gate voltage is higher than the saturation voltage of the readout buffer at least by a threshold voltage. The gate voltage of the first transistor is adjusted during the reset phase to the highest value which will be used during the integration phase, but at least higher than the ground voltage by a threshold voltage and lower than the gate voltage of the second transistor. During the holding phase, the gate voltage of the first transistor is adjusted to the same value as during the reset phase, but at least higher than the ground voltage by a threshold voltage.

As more generally mentioned above, according to a preferred embodiment of said method the gate voltage of the second transistor may be varied during the integration phase, although it always remains greater than the gate voltage of the first transistor, and the gate voltage of the first transistor is preferably reduced successively during the integration phase.

In addition, it is furthermore possible to keep the gate voltage of the first transistor constant or successively reduce it during the integration time. Furthermore, a procedure may be adopted such that the gate voltage of the second transistor is switched at least once so that it is equal to the bulk potential of this transistor and is switched back again to its original value.

The present invention furthermore relates to a one- or two-dimensional array of optoelectronic sensors as described above. It also relates to a method for operating such an array.

### BRIEF DESCRIPTION OF THE DRAWINGS

The invention will be explained in more detail below with reference to the drawings, in which:

FIG. 1 shows a circuit diagram of an optoelectronic sensor having reduced sensitivity at high intensities;

FIG. 2 shows a circuit diagram of an optoelectronic sensor having reduced sensitivity at high intensities, with a shutter transistor and conversion node capacitor;

FIG. 3 shows a circuit diagram of an optoelectronic sensor having a large dynamic range (preferred implementation of the circuit according to the invention);

FIG. 4 shows a circuit diagram of an optoelectronic sensor having increased sensitivity at low intensities; and

FIG. 5 shows a circuit diagram of an optoelectronic sensor having a large dynamic range, in which the first transistor is replaced by a diode.

### EMBODIMENTS OF THE INVENTION

A) Nonlinear Characteristic Curve by Reducing the Sensitivity at High Optical Intensities

In integrating photodetectors, the optically generated charge is accumulated by a reverse-biased photodiode 1 and integrated on the stray capacitance of the photodiode and the capacitors connected to the photodiode.

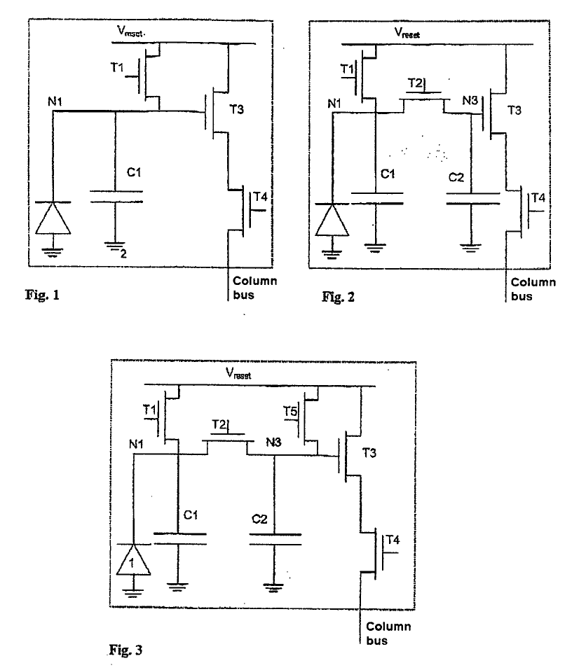

A reduction in the sensitivity at high intensities can be achieved if a particular signal-dependent current is drawn off after the integration capacitor C1, C2 has reached a certain signal level (for example, this is proposed in the aforementioned WO 01/46655). This can be achieved if, in a pixel diagram according to one of FIGS. 1-3, the gate of the MOS transistor T1 is biased during the integration phase so that beyond an intended signal value, the MOS transistor T1 discharges a signal-dependent current from the integration capacitor C1 by subthreshold conductance (conductance below the threshold value). During the integration time, the biasing of the gate of this transistor T1 may be adapted so that different effective integration times are produced for different optical intensities. This is implemented as follows in an embodiment with an N-type photodiode against a P-type substrate and with N-channel MOS transistors:

Before the start of integration time, the gate of the reset transistor T1 in FIGS. 1-3 is biased to at least a threshold value more than the reset potential Vᵣₑₛₑₜ. The integration capacitor C1 in FIG. 1, or respectively C1 and C2 in FIGS. 2 and 3, is thereby charged to the reset potential Vᵣₑₛₑₜ. At the start of integration time, the gate of the reset transistor T1 is biased (VG1) to a value lower than the reset potential plus the threshold voltage, but higher than the saturation voltage of the readout buffer at least by a threshold voltage. The current accumulated by the photodiode 1, which responds linearly to the incident light intensity, discharges the integration capacitor C1, or respectively C1 and C2. For relatively high optical intensities, the integration capacitor will discharge to the value VG1−VTH (threshold voltage of T1) within the integration time. From this time onward, the transistor T1 discharges some of the current generated by the photodiode 1 from the integration capacitor. The voltage at the integration capacitor now decreases more slowly until it finally stabilizes at a value with which all of the current generated by the photodiode 1 is compensated for via the transistor T1. In the second half of the integration time, for example after 90% of the integration time, the gate of the reset transistor T1 is biased to a lower value VG2. This stops the compensation for the current generated by the photodiode 1. The integration capacitor is again discharged by the entire photocurrent. Since a shorter time span remains until the end of the integration time, this results in a reduced sensitivity for optical intensities which have discharged the integration capacitor to VG1−VTH in the first time interval.

The characteristic curve can be tailored to requirements by adding further stages.

B) Nonlinear Characteristic Curve by Increasing the Sensitivity for Small Signals

An increase in the sensitivity of integrating optoelectronic sensors in CMOS technology can be achieved by reducing the conversion capacitance which converts the photogenerated charges into a voltage signal. Usually, the capacitance is formed by the stray capacitance of the photodiode and the stray capacitances of the readout electronics connected to the photodiode. These capacitances can only be reduced to a limited extent by the minimal structures that can be produced in a given technology. By adding an MOS transistor and suitable biasing of the gate voltage of this transistor between the photodiode and the readout buffer, it is possible to separate the stray capacitance of the photodiode from the conversion capacitor.

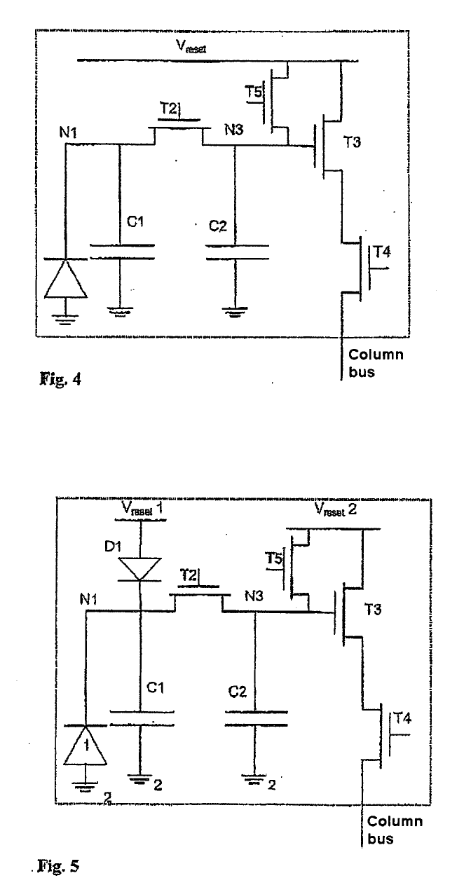

An example circuit of an optoelectronic sensor which makes this possible is given in FIG. 4.

In a first phase, by closing the reset transistor T5, the conversion capacitor C2 is charged to the reset voltage Vᵣₑₛₑₜ. The gate of the transistor T2 is kept at a constant voltage VGT2 during the reset phase. This voltage is selected so that the gate voltage of the MOS transistor T2 minus a threshold voltage is less than the reset voltage which is achieved at the conversion node N3 by opening the reset transistor T5. The gate voltage, however, is selected to be higher than the bulk potential of the transistor T2 at least by a threshold voltage. The photodiode 1 is not therefore brought to the reset potential during the reset, but is stabilized at a potential VGT2−VTH.

Charge carriers which are collected by the photodiode generate a current in the transistor T2, which discharges the conversion capacitor C2. The reverse bias voltage of the photodiode 1 is thus maintained. As a result of this, the stray capacitance C1 of the photodiode 1 is not discharged, and the voltage signal which is generated for a particular amount of charge accumulated on C2 is greater than when the conversion capacitor is connected directly to the photodiode 1. This increased sensitivity is achieved so long as the voltage at the conversion node N3 is greater than the voltage at the photodiode (N1). As soon as the two voltages equalize, the stray capacitances of the photodiode and of the conversion node N3 discharge uniformly. The sensitivity is therefore reduced for larger signals.

The end of the integration time may be determined by reducing the gate voltage at T2 to a potential lower than the bulk potential plus a threshold voltage (opening C2) and sampling the voltage signal on C2, or by reading out and inducing the reset. The photodiode can discharge further during the holding phase. The effect of this may be that the photodiode discharges fully, and optically generated charges overflow through the substrate to the storage node and then falsify the signal value being read out. The invention offers a solution to this problem.

During the integration time, the gate voltage of the transistor T2 may be modified in order to increase the sensitivity by means of signal-dependent charge injection. (For example, repeatedly opening and closing to VGT2.)

According to the invention, the following procedure is then adopted:

The circuit diagram of the exemplary embodiment of an optoelectronic sensor according to the invention is depicted in FIG. 3. The optoelectronic sensor according to the invention has a photodiode 1, which can be connected to a reset voltage Vᵣₑₛₑₜ by means of an MOS transistor T1. The sensor also has an MOS transistor T2, which connects the photodiode to the readout buffer T3. The input terminal of the readout buffer T3 is furthermore connected by an MOS transistor T5 to the reset potential.

In the inventive control of the sensor, the gate terminal of the transistor T2 is biased during the reset and integration phases so that the gate voltage minus the threshold voltage is lower than the reset potential, which is set at the input of the readout buffer N3, but higher than the saturation signal of the readout buffer T3 at least by a threshold voltage.

The gate of the transistor T1 is biased so that its potential is lower than the gate potential of T2, but higher than the saturation signal of the readout buffer T3 at least by a threshold voltage. The difference between the two gate voltages should be greater than the tolerance of the threshold voltages plus the tolerance of the voltage values (typically >100 mV).

During the integration phase, the potential of the transistor T2 may be varied but should always remain greater than the gate potential of the transistor T1.

The gate potential of the transistor T1 may be reduced during the integration phase.

In a first phase of the integration time, charge carriers accumulated by the photodiode 1 discharge only the conversion capacitor C2, and generate a maximum voltage signal per charge carrier. For relatively small optical intensities, the sensor according to the invention remains in this phase throughout the integration time.

In the second phase of the integration time, the potentials at the nodes N1 and N3 equalize. In this phase, charge carriers collected by the photodiode 1 discharge the stray capacitance C1 of the photodiode 1 uniformly with the conversion capacitor C2, and generate a medium voltage signal per charge carrier. For medium optical intensities, the sensor according to the invention remains in this phase until the end of the integration time.

In a third phase of the integration time, the stray capacitances of the photodiode 1 and of the readout node are discharged until some or all of the current generated by the photodiode is compensated for by means of the transistor T1. Depending on whether a logarithmic response or a locally linear response is desired in this part of the characteristic curve, the gate potential of T1 may be reduced stepwise or continuously by a known technique, or kept at a suitable fixed value.

At the end of the integration time, the voltage signal which is established at the node N3 is sampled by reducing the gate potential of T2 to a value lower than the bulk potential plus a threshold voltage (opening T2). Until the voltage signal is read out, the gate potential of T1 remains higher than the ground potential at least by a threshold voltage. This prevents the stray photodiode capacitance from discharging fully, and surplus charges from overflowing to the storage node. After the voltage signal at N3 has been read out by means of the readout buffer, the node N3 is brought to the reset potential Vᵣₑₛₑₜ by means of the reset transistor T5 and the gate of the transistor T1 is set to the value at the start of the integration time.

FIG. 5 shows an alternative circuit, in which the first transistor T1 is replaced by a diode D1. In order to make this diode D1 fulfill a similar task, in this case the reset potentials of the diode D1 and the transistor T5 must be made different. A reset potential Vᵣₑₛₑₜ₁ is applied to the diode D1 (in an alternative embodiment, this potential can be controlled during the integration time) while the potential Vᵣₑₛₑₜ₂ is applied to the transistor T5 or T3, respectively.

In such a circuit according to FIG. 5, a reduction in the sensitivity for high intensities can be achieved if a particular signal-dependent current is drawn off after the integration capacitor C1, C2 has reached a certain signal level (for example, this is done in the aforementioned WO 01/46655). In a pixel diagram according to FIG. 5, this is achieved by adjusting the reset voltage Vᵣₑₛₑₜ₁ of the diode D1 during the integration phase so that beyond an intended signal value, the diode D1 discharges a signal-dependent current from the integration capacitor C1 by conductance above the threshold value. During the integration time, the voltage Vᵣₑₛₑₜ₁ at the diode D1 may be adapted so that different effective integration times are produced for different optical intensities. This is for an embodiment with an N-type photodiode against a P+/N-well junction diode D1 (typically with a threshold potential V_{onDiode} in the range from 0.3 to 0.7 V).

In a first phase, by closing the reset transistor T5, the conversion capacitor C2 is charged to the reset voltage Vᵣₑₛₑₜ. The gate of the transistor T2 is kept at a constant voltage VGT2 during the reset phase. This voltage is selected so that the gate voltage of the MOS transistor T2 minus a threshold voltage is less than the reset voltage which is achieved at the conversion node N3 by opening the reset transistor T5. The gate voltage, however, is selected to be higher than the bulk potential of the transistor T2 at least by a threshold voltage. The photodiode 1 is not therefore brought to the reset potential during the reset, but is stabilized at a potential VGT2−VTH.

In this phase, the reset voltage Vᵣₑₛₑₜ₁ in FIG. 5 is set to the highest value used during the integration. This voltage minus the threshold voltage of the diode (D1) is at least higher than the saturation value of the readout buffer but lower than the gate voltage minus the threshold voltage of the second transistor (T2 in FIG. 5) (typically >100 mV). The current collected by the photodiode 1, which responds linearly to the incident light intensity, is compensated for in a first phase by the channel of the MOS transistor T2 and discharges only the capacitor C2. As soon as the potential at N3 has discharged to a value lower than the gate voltage of T2 minus the threshold voltage, the capacitors C1 and C2 are discharged uniformly. For relatively high optical intensities, the integration capacitance (C1+C2) is discharged to the value (Vᵣₑₛₑₜ₁−V_{onDiode}) within the integration time. From this time onward, the diode D1 discharges some of the current generated by the photodiode 1 from the integration capacitor. The voltage at the integration capacitor now decreases more slowly until it finally stabilizes at a value with which all of the current generated by the photodiode 1 is compensated for via the diode D1. In another phase of the integration time, for example after 90% of the integration time, the reset voltage Vᵣₑₛₑₜ₁ is set to a lower value. This stops the compensation for the current generated by the photodiode 1. The integration capacitor is again discharged by the entire photocurrent. Since a shorter time span remains until the end of the integration time, this results in a reduced sensitivity for optical intensities which have discharged the integration capacitor to Vᵣₑₛₑₜ₁−V_{onDiode} in the first time interval.

The characteristic curve can here again be tailored to requirements by adding further stages.

### LIST OF REFERENCES

1 photodiode
2 ground potential
C1 photodiode capacitor
C2 conversion node capacitor
T1 reset transistor
T2 shutter transistor
T3 readout transistor
T4 row selection transistor
T5 reset transistor of the sense node N2
N1 diode node
N3 conversion node/storage node
Vᵣₑₛₑₜ reset voltage
Vᵣₑₛₑₜ₁ reset voltage on diode D1
Vᵣₑₛₑₜ₂ reset voltage on transistor T5
V_{onDiode} diode threshold voltage
D1 reset diode

1. An optoelectronic sensor comprising at least one photodiode (1) which can be connected to a first potential (Vᵣₑₛₑₜ, Vᵣₑₛₑₜ₁) via a first transistor (T1) or a first diode (D1),
characterized in that
in order to provide a large dynamic range, the photodiode (1) can furthermore be connected to the input of a readout amplifier (T3) via a second transistor (T2), a third transistor (T5) via which the input of the readout amplifier (T3) can be connected to a second potential (Vᵣₑₛₑₜ, Vᵣₑₛₑₜ₂) furthermore being arranged between the second transistor (T2) and the input of the readout amplifier (T3), and
in that there are means (C2) which allow temporary storage of the integrated signal value until the readout time.

2. The optoelectronic sensor as claimed in claim 1, characterized in that there is a first transistor (T1), and in that the first and second potentials (Vᵣₑₛₑₜ) are at an essentially identical voltage level.

3. The optoelectronic sensor as claimed in claim 1, characterized in that an additional conversion node capacitor (C2) to ground potential (2) is arranged between the second transistor (T2) and the input of the readout amplifier (T3).

4. The optoelectronic sensor as claimed in claim 1, characterized in that the output of the readout amplifier (T3) is connected to a column bus via a row selection transistor (T4).

5. The optoelectronic sensor as claimed in claim 1, characterized in that at least one, and preferably all of the transistors (T1, T2, T3, T4, T5) used are designed as MOS transistors.

6. The optoelectronic sensor as claimed in claim 1, characterized in that the gate voltage of the second transistor (T2) is controlled so that the current generated by the photodiode (1) discharges only a capacitor (C2) at the input of the readout amplifier (T3) in a first phase of the integration time, and in that the gate voltage of the first transistor (T1), or respectively the first potential (Vᵣₑₛₑₜ₁) when there is a first diode (D1), is in this case controlled so that some or all of the current generated by the photodiode (1) is compensated for by the channel of the first transistor (T1) or respectively by the first diode (D1) in a last phase of the integration time.

7. The optoelectronic sensor as claimed in claim 6, characterized in that in the case of a first transistor (T1) the gate voltage of the first transistor (T1) is lower than the gate voltage of the second transistor (T2) and in that the gate voltage of the first transistor (T1) is higher than the saturation signal of the readout buffer at least by a threshold voltage, or respectively in that in the case of a first diode (D1) the diode anode voltage of the first diode (D1) is adjusted by the first potential (Vᵣₑₛₑₜ₁) so that this anode voltage minus the diode threshold voltage (Vᵣₑₛₑₜ₁−V_{onDiode}) is lower than the gate voltage minus the threshold voltage of the second transistor (T2) and in that the diode anode voltage (Vᵣₑₛₑₜ₁) of the first diode (D1) is higher than the saturation signal of the readout buffer at least by a diode threshold voltage (V_{onDiode}).

8. The optoelectronic sensor as claimed in claim 6, characterized in that the difference between the two gate voltages is greater than the tolerance of the threshold voltages plus the tolerance of the voltage values, this difference particularly preferably being selected to be >100 mV.

9. The optoelectronic sensor as claimed in claim 1, characterized in that the gate voltages of the first transistor (T1) and of the second transistor (T2) can be varied during the integration time.

10. A method for operating an optoelectronic sensor as claimed in claim 1, characterized in that the gate voltage of the first transistor (T1), or respectively the first potential (Vᵣₑₛₑₜ₁) in the case of a first diode (D1), and the gate voltage of the second transistor (T2), is respectively adjusted or controlled so that charge carriers accumulated by the photodiode (1) discharge only a conversion node capacitor (C2) in a first phase of the integration time, in that charge carriers accumulated by the photodiode (1) discharge both a photodiode capacitor (C1) and said conversion node capacitor (C2) in a second phase after an equal potential has been reached at the output of the photodiode (1) and at the input of the readout amplifier (T3), and in that after the output of the photodiode (1) has fallen below the threshold value of the first transistor (T1) or respectively the diode threshold value of the first diode (D1), charge carriers accumulated by the photodiode (1) are at least partially made available via the first transistor (T1) or respectively via the first diode (D1) in a third phase, and in that said second transistor (T2) is opened after the integration time has elapsed so that the signal is held at the conversion capacitor (C2) until the readout time and in that the first transistor (T1) or respectively the first diode (D1) is adjusted during this holding time so that the photodiode capacitor (C1) is not fully discharged.

11. The method as claimed in claim 10, characterized in that the gate voltage of the second transistor (T2) is adjusted during the reset phase and during the integration phase so that the gate voltage minus the threshold voltage is lower than the reset voltage which is set at the input of the readout amplifier (T3), and in that the gate voltage is higher than the saturation voltage of the readout buffer at least by a threshold voltage.

12. The method as claimed in claim 10, characterized in that the gate voltage of the second transistor (T2) is varied during the integration phase, although it always remains greater than the gate voltage of the first transistor (T1), and in that the gate voltage of the first transistor (T1) is preferably reduced successively during the integration phase.

13. The method as claimed in claim 10, characterized in that the gate voltage of the first transistor (T1) is kept constant or successively reduced during the integration time.

14. The method as claimed in claim 10, characterized in that the gate voltage of the second transistor (T2) is switched at least once so that it is equal to the bulk potential of this transistor (T2) and is switched back again to its original value.

15. A one- or two-dimensional array of optoelectronic sensors as claimed in claim 1.

16. A method according to claim 10 for operating an array as claimed in claim 15.
